(19) United States
(12) Patent Application Publication
(10) Pub. No.: US 2002/0177079 A1
(43) Pub. Date: Nov. 28, 2002

(54) Method of manufacturing a reflector

(76) Inventor: Chung-Yuan Liu, Tai-Nan City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,893

(22) Filed: May 22, 2002

(30) Foreign Application Priority Data
May 23, 2001 (TW) 090112448

(51) Int. Cl. B05D 5/12; B05D 1/36; G03F 7/00

(52) U.S. Cl. 430/313; 427/58; 427/402; 430/317

(57) ABSTRACT

A method of manufacturing a bumpy reflector utilizes a process of forming thin film transistors to fabricate bumps simultaneously, thereby reducing the frequency of using photo masks. Additionally, by varying positions, numbers, and widths of the deposition layers, the bumps of different heights and widths are formed, and therefore, the bumpy reflector has a better effect on reflecting light beams. Furthermore, a photosensitive organic layer with a molten characteristic is used to replace a passivation layer and a photoresist layer, which can simplify the fabrication processes of manufacturing a reflector. Consequently, an LCD of good quality and low production cost is manufactured.

### BACKGROUND OF INVENTION

1. Field of the Invention

The present invention relates to a method for manufacturing a liquid crystal display (LCD), and more particularly, to a method for manufacturing a reflector of an LCD.

2. Description of the Prior Art

LCDs were first applied in electronic calculators and digital timepieces in 1970. At the present time, LCDs have been used in notebooks, TVs, and word processors, and these applications are dramatically popular nowadays. Although the most widely used electronic displays are made of a cathode ray tube (CRT), the CRT has shortcomings such as heavy weight, large size, and high power consumption.

One of the problems of an LCD is low reflectivity. Generally, the reflectivity of newspapers is about 57% of that of standard whiteboards, and that of twisted-nematic (TN) black and white (BW) crystal displays is usually below 25%. Although the contrast ratio of TN BW crystal displays can reach above 5:1, due to its low reflectivity, users still suffer the inconvenience of low reflective brightness and narrow viewing angles. In order to improve the reflectivity, reflectors are usually formed in a liquid crystal layer of an LCD so as to increase the reflection of light beams.

Please refer to FIG. 1. FIG. 1 is a schematic diagram of a prior art LCD having a mirror reflector. The prior art LCD comprises a substrate 54, a mirror reflector 56, a liquid crystal layer 58, a transparent conductive film 60, a transparent substrate 62, a diffuser 64, a retardation film 66, and a polarizer 68. In order to overcome the problem of weak reflection intensity, the mirror reflector 56 is formed under the liquid crystal layer 58 of the prior art LCD to improve the reflection intensity. Accordingly, the reflectivity of the incident light 50 can be enhanced, thus increasing intensity of the reflection light 52.

LCDs are also widely used in digital products such as portable computers and personal digital assistants (PDAs). If only the structures of a mirror reflector and a diffuser are used in an LCD, users always have to fix their viewing angle within a specific range of reflection angles. Otherwise, they cannot see the displayed contents clearly and that leads to a lot of inconveniences. As a matter of fact, while operating the portable computers or PDAs, due to personal habits and environments, users usually maintain their viewing angles approximately within a predetermined range, which is not necessary identical to the specific range of reflection angles. To overcome this drawback, another LCD structure is developed as shown in FIG. 2. FIG. 2 is a schematic diagram of an LCD having a bumpy reflector. In comparison with the prior art LCD, the geometry of the reflector is changed in the LCD having a bumpy reflector. Since the surface of the bumpy reflector has a plurality of bumps, the incident light is reflected at different angles so as to increase the brightness within a particular region. Thus, the drawback that the brightness is concentrated on an angle is prevented. The reflective light can equally distribute within the particular region.

Please refer to FIG. 3 to FIG. 8. FIG. 3 to FIG. 8 are schematic diagrams of manufacturing a prior art bumpy reflector. As shown in FIG. 3, a substrate 100 is covered with a photoresist layer 102a which is an organic material having a molten characteristic. Thereafter, by using a photo mask 104, exposing and a development processes are in turn performed on the photoresist layer 102a, as shown in FIG. 4. Therefore, as shown in FIG. 5, a plurality of bumps 102b is formed on the substrate 100. Then, a baking process is performed to melt the bumps 102b shown in FIG. 5. Smooth bumps 102c are formed, as shown in FIG. 6. Subsequently, as shown in FIG. 7, the structure shown in FIG. 6 is covered with an organic insulating film so as to form a smooth bumpy surface. The organic insulating film 106 is covered with a metal layer 108 functioning as a reflector, as shown in FIG. 8. After performing the above-mentioned processes, the bumpy reflector is completed.

In addition, another method of manufacturing a bumpy reflector utilizes a stacked structure to form a bump, and the stacked structure is formed from a material selected from the group consisting of a gate

electrode layer, an insulating layer, an amorphous silicon layer, and a metal layer. Please refer to FIG. 9. FIG. 9 is a structural diagram of prior art thin film transistors and bumps. As shown in FIG. 9, a transparent substrate 120 is sequentially covered with the gate electrode layer 122, the insulating layer 124, the amorphous silicon layer 126, and the metal layer 128. Then, an identical etching process is performed on these layers to define these bumps. Following that, an organic layer 130 and a metal layer 132 are formed on the bumps, so that the prior art bumpy reflector is completed.

As mentioned above, the prior art method for manufacturing a reflector utilizes a photolithography process to define bump structures. However, the photo masks, used for defining a photoresist layer, have high costs and long production time, which would lead to a bottleneck for manufacturing an LCD and increasing a production cost. In addition, another prior art method for manufacturing a reflector utilizes an identical etching process to etch a gate electrode layer, an insulating layer, an amorphous silicon layer, and a metal layer. However, the stacked structures made by the prior art method have both identical heights and widths, which brings about ineffectively distributing the reflecting light. Furthermore, as using the prior art method for making bumps, an etchant capable of simultaneously etching a metal layer and a non-metal layer is required, which causes an inconvenience for selecting an etchant.

### SUMMARY OF INVENTION

Therefore, it is an objective of the claimed invention to provide a method for manufacturing a reflector that makes thin film transistors that are accompanied with defining stacked structures used for making bumps.

It is another objective of the claimed invention to provide a method for manufacturing a reflector that uses deposition layers of different shapes, positions, and numbers to form bump structures of variable shapes, heights, and widths.

It is another objective of the claimed invention to provide a method for manufacturing a reflector that uses a photosensitive organic layer to replace an inorganic passivation layer and a photoresist layer, thereby simplifying fabrication processes for making a reflector. Moreover, due to a molten characteristic of the organic layer, the organic layer is smoothened after performing a baking process, and the bump structures having smooth surfaces are therefore produced.

According to the above-mentioned objectives, the claimed invention provides a method for manufacturing a reflector that is compatible with thin film transistors of the prior art LCD, omits the use of photo masks, and simplifies fabrication processes for making a reflector. Accordingly, bump structures and smooth surfaces are formed to prevent large reflection angles, increase effective reflection intensity, and improve the quality of an LCD.

The manufacturing method of the claimed invention is described as follows.

Firstly, a substrate is provided. A thin film transistor and a plurality of stacked structures are concurrently formed on the substrate. Each of the stacked structures comprises a plurality of sub-stacked layers, such as a gate electrode layer, an insulating layer, an amorphous silicon layer, an N⁺ silicon layer, and a metal layer. Additionally, the sub-stacked layers have at least two different kinds of widths. Then, an inorganic passivation layer is formed to cover the thin film transistor and the stacked structures. An organic layer having a molten characteristic is formed to cover the inorganic passivation layer. Following that, a photoresist layer for defining a contact hole is formed to cover the organic layer. After forming the contact hole, the photoresist layer is removed. Thereafter, a baking process is performed to smoothen the organic layer, and finally, a metal reflective layer is formed to cover the organic layer. As a result, a bumpy reflector of the claimed invention is completed.

Another manufacturing method of the claimed invention, which uses an organic layer to replace a photoresist layer for defining a contact hole, is described as follows.

After forming a plurality of above-mentioned stacked structures, an inorganic passivation layer is formed to cover the thin film transistor and the stacked structures. Then, an organic layer having a molten characteristic is formed to cover the inorganic passivation layer, and the organic layer can further function as a photoresist layer for defining a contact hole. After forming the contact hole, the organic layer is still preserved. Subsequently, a baking process is performed to smoothen the organic layer and then a metal reflective layer is formed on the smoothened organic layer. A bumpy reflector of the claimed invention is therefore completed.

Another manufacturing method of the claimed invention, which uses an organic layer to replace a passivation layer and a photoresist layer for defining a contact hole, is described as follows.

After forming a plurality of above-mentioned stacked structures, an organic passivation layer is formed to cover the thin film transistor and the stacked structures. The organic passivation layer is a photosensitive resin having a molten characteristic so that it can function as a photoresist layer for defining a contact hole. After forming the contact hole, the organic passivation layer is still preserved. Thereafter, a baking process is performed to smoothen the organic passivation layer and then a metal reflective layer is formed on the organic passivation layer. Consequently, a bumpy reflector of the claimed invention is completed.

In the above-mentioned manufacturing method of the claimed invention, the steps of defining the contact hole and baking the organic layer can be swapped, which is capable of making a bumpy reflector that is the same as the above-mentioned bumpy reflector.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a schematic diagram of a prior art LCD having a mirror reflector.

FIG. 2 is a schematic diagram of an LCD having a bumpy reflector.

FIG. 3 to FIG. 8 are schematic diagrams of manufacturing a prior art bumpy reflector.

FIG. 9 is a structural diagram of prior art thin film transistors and bumps.

FIG. 10 to FIG. 20 are schematic diagrams of manufacturing a bumpy reflector according to the present invention.

FIG. 21 to FIG. 25 are schematic diagrams of manufacturing a bumpy reflector according to the present invention.

FIG. 26 to FIG. 29 are schematic diagrams of manufacturing a bumpy reflector according to the present invention.

FIG. 30 is a schematic diagram of stacked structures of bumps according to the present invention.

FIG. 31a is a cross-sectional view of a stacked structure of a bump according to the present invention.

FIG. 31b is a top view of the stacked structure of the bump shown in FIG. 31a.

FIG. 32a is a cross-sectional view of another stacked structure of a bump according to the present invention.

FIG. 32b and FIG. 32c are top views of the stacked structure of the bump shown in FIG. 32a.

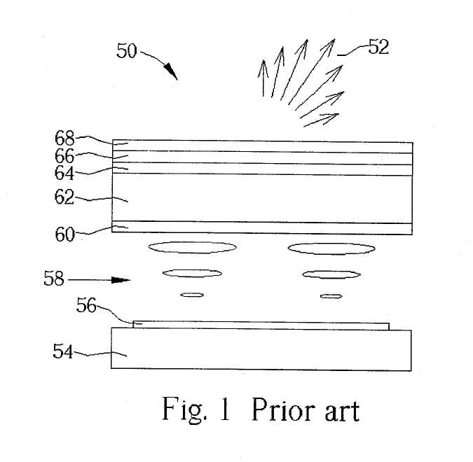

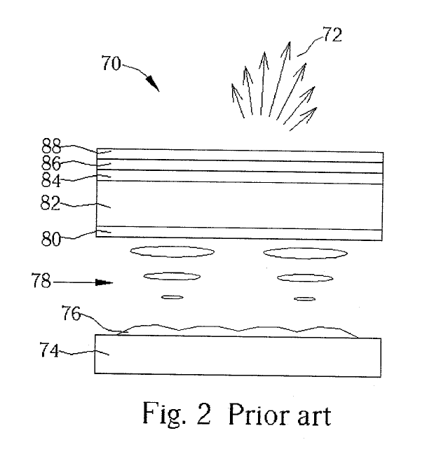

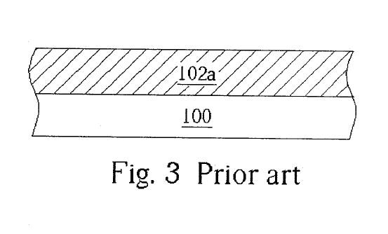

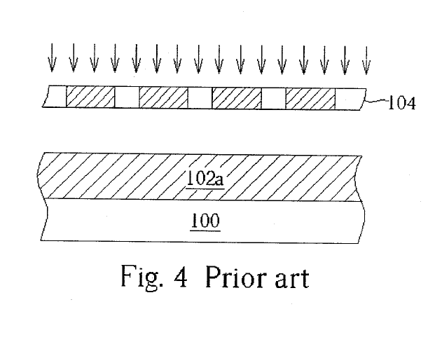

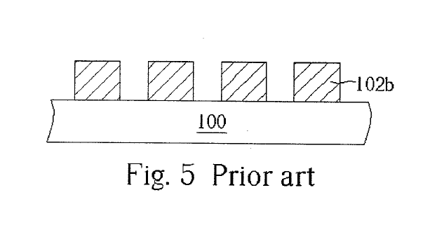

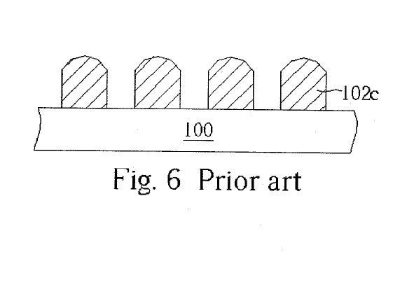

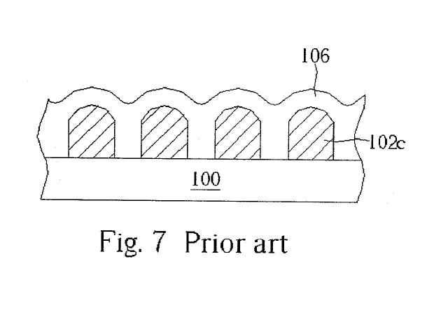

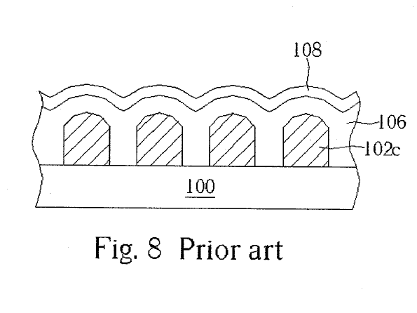

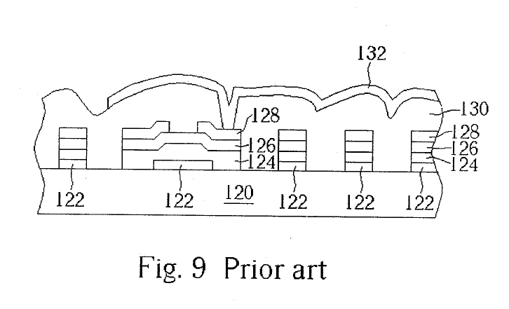

### DETAILED DESCRIPTION

The prior art method for manufacturing a bumpy reflector utilizes a photoresist layer as bump structures of bumps. A photolithography process is firstly performed to define the shape of each bump, and then an organic layer is formed to cover the bump structures. The above-mentioned photolithography process makes it complex to manufacture the bumpy reflector. Furthermore, an additional photo mask is required in the photolithography process, which leads to increasing production cost. In addition, another prior art method of manufacturing a bumpy reflector uses an identical etching process to define bump structures. Nevertheless, each of the bump structures has an identical height as well as a same width. As a result, the bumpy reflector reflects light beams ineffectively.

The present invention provides a method for manufacturing a reflector by use of deposition layers required for fabricating a thin film transistor, such as a gate electrode layer, an insulating layer, an amorphous silicon layer, an N silicon layer, and a metal layer. Those deposition layers are utilized to form a plurality of stacked structures for forming bumps, which have different shapes, heights, and sizes.

Furthermore, the present invention makes use of an organic layer that can function as a photoresist material for defining a contact hole. The organic layer has a molten characteristic so that it can be used as a passivation layer and a photoresist layer concurrently, which makes fabrication processes simplified.

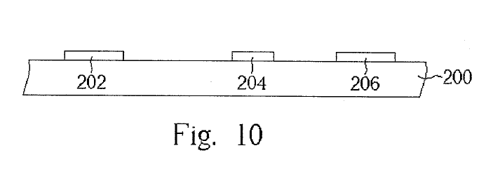

FIG. 10 to FIG. 20 are schematic diagrams of manufacturing a bumpy reflector according to the present invention. The method of manufacturing a reflector according to the present invention is described as follows.

Please refer to FIG. 10. A substrate 200, such as transparent glass, is provided and is covered with a gate electrode material. After performing a photolithography process on the gate electrode material, gate electrode layers 202, 204, 206 are formed. The gate electrode layer 202 is used for making a thin film transistor. The gate electrode layers 204, 206 are used for making bumps.

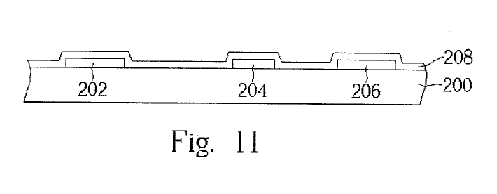

Please refer to FIG. 11. An insulating layer 208 is formed on the substrate 200, and the gate electrode layers 202, 204, 206 by performing a chemical vapor deposition (CVD) process. Additionally, the insulating layer 208 is composed of silicon nitride (SiNₓ).

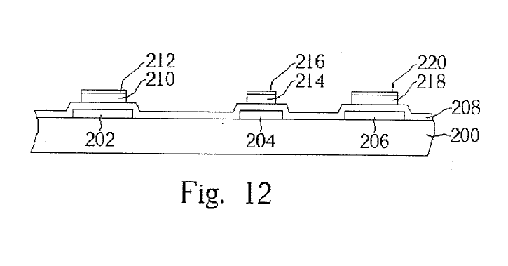

Please refer to FIG. 12. An amorphous silicon material and an N³⁰ silicon material are formed on the insulating layer 208. Then, a photolithography process is performed to define amorphous silicon layers 210, 214,218, and N⁺ silicon layers 212,216, 220. The amorphous silicon layer 210 and the N⁺ silicon layer 212 are used for making the thin film transistor. The amorphous silicon layers 214, 218, and the N silicon layers 216, 220 are used for making bumps.

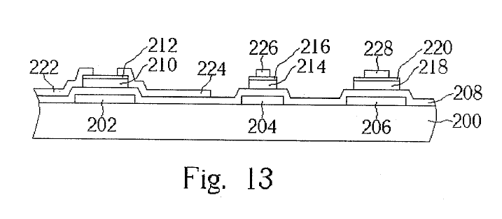

Referring to FIG. 13, a metal material is formed on the structure shown in FIG. 12. Then, a photolithography process is performed to define metal layers 222, 224, 226, 228. The metal layers 222, 224 are used as a source and a drain of the thin film transistor. Furthermore, the metal layers 226, 228 are used for making bumps.

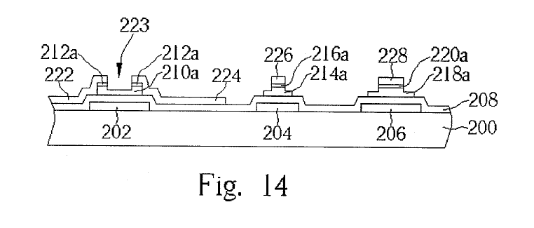

Please refer to FIG. 14. An etching process is performed to remove the amorphous silicon layer 210 and the N⁺ silicon layer 212, which are uncovered with the metal layers 222, 224, so as to form an etching region 223. During performing the etching process, the amorphous silicon layer 214 and the N⁺ silicon layer 216, which are uncovered with the metal layers 226, are partially removed. In the mean time, the amorphous silicon layer 218 and the N silicon layer 220, which are uncovered with the metal layers 228, are partially removed during performing the etching process. Thus, amorphous silicon layers 214a, 218a, and N⁺ silicon layers 216a, 220a have been formed. As a result, the stacked structures of the bumps in the present invention are completed.

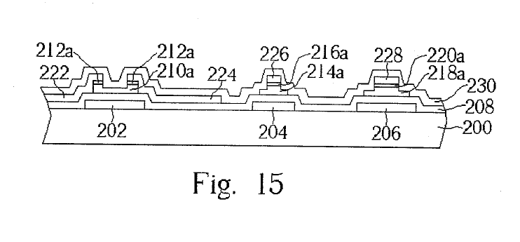

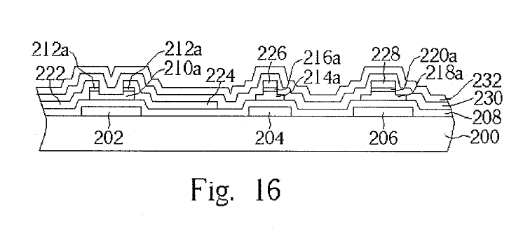

Please refer to FIG. 15. An inorganic passivation layer 230 is formed on the structure shown in FIG. 14. The inorganic passivation layer 230 is composed of silicon nitride (SiN_{X}), which is formed by use of a chemical vapor deposition process. Then, as shown in FIG. 16, an organic layer 232 with a molten characteristic is formed on the structure shown in FIG. 15.

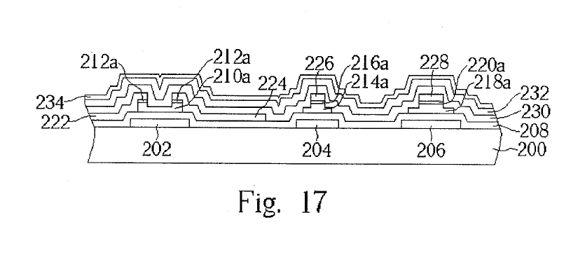

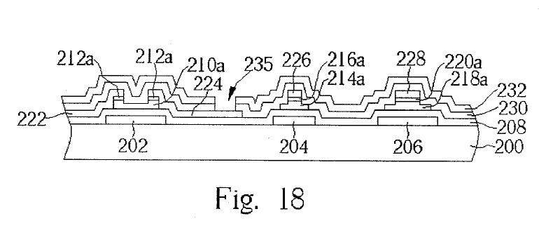

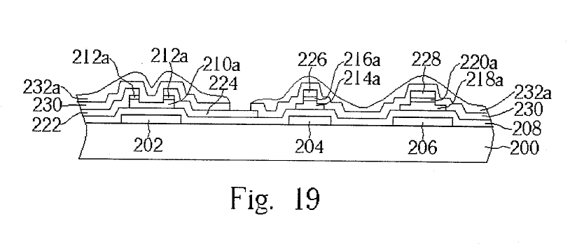

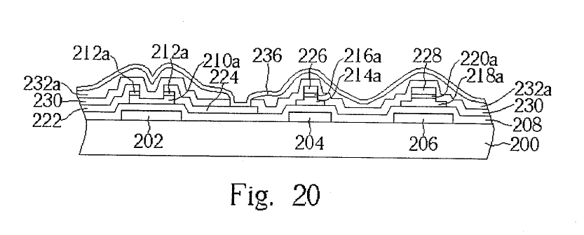

Then, a process for defining a contact hole is performed. Referring to FIG. 17, a photoresist layer 234 is formed on the structure shown in FIG. 16. Thereafter, a contact hole 235 is formed by performing an etching process, and subsequently, the photoresist layer 234 is removed as shown in FIG. 18. After that, a baking process is performed on the organic layer 232 to form an organic layer 232a with a smooth surface. Therefore, the bumps have smooth surfaces and can produce better effects on scattering light beams, as shown in FIG. 19. Then, please refer to FIG. 20. A metal reflective layer 236, such as aluminum, is formed on the structure shown in FIG. 19. The metal reflective layer 236 is used to reflect light beams. Thus, the bumpy reflector of the present invention is completed.

In the above-mentioned method for manufacturing the bumpy reflector, order of defining the contact hole and baking the organic layer can be swapped. That is, the baking process is firstly performed on the organic layer 232, and then, the photoresist layer 234 is formed on the organic layer 232. Thereafter, the contact hole 235 is formed by performing an etching process. Then, the photoresist layer 234 is removed. After that, the metal reflective layer 236 is formed on the above-mentioned structure. As a result, the bumpy reflector of the present invention is completed.

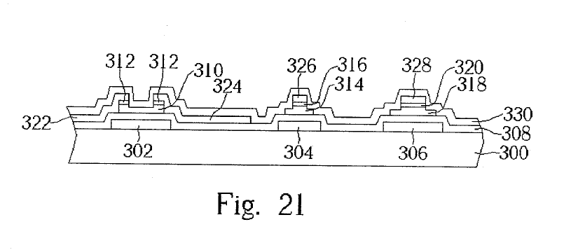

In addition, the present invention provides another method for manufacturing a reflector, which can simplify fabrication processes. FIG. 21 to FIG. 25 are schematic diagrams of manufacturing a bumpy reflector according to the present invention.

According to the process flow shown in FIG. 10 to FIG. 14, gate electrode layers 302, 304, 306 are formed on the substrate 300. The gate electrode layer 302 is used for making a thin film transistor, as well as the gate electrode layers 304, 306 are used for making bumps. An insulating layer 308 is formed on the substrate 300 and the gate electrode layers 302, 304, 306. An amorphous silicon layer 310 and an N⁺ silicon layer 312, which are required for fabricating the thin film transistor, are formed. At the same time, amorphous silicon layers 314, 318 and N⁺ silicon layers 316, 320, which are required for making the bumps, are formed. Thereafter, metal layers 322, 324, 326, 328 are formed. The metal layers 322, 324 are used for the thin film transistor, and the metal layers 326, 328 are required for making the bumps. After that, an etching process is performed. The stacked structures, like the stacked structures shown in FIG. 14, are completed.

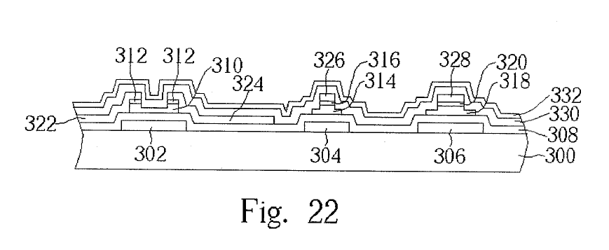

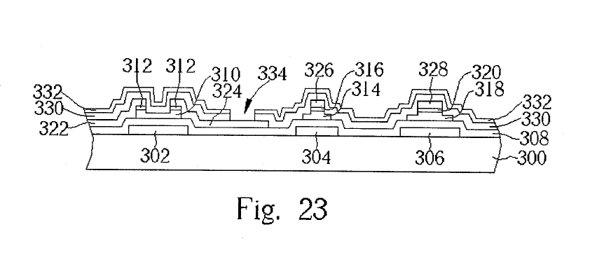

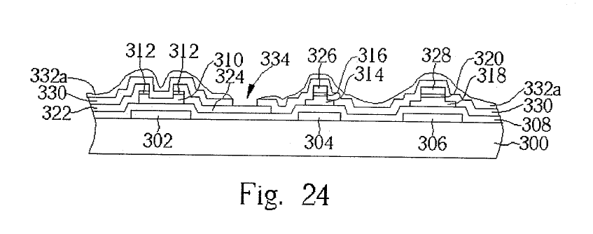

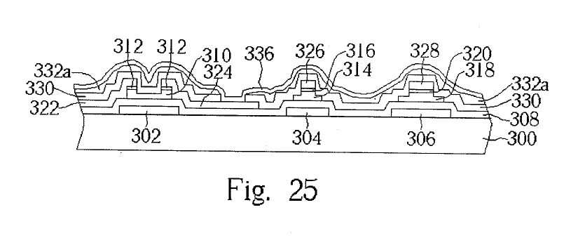

Please refer to FIG. 21. An inorganic passivation layer 330 is formed. Referring to FIG. 22, an organic layer 232 is formed on the structure shown in FIG. 21. The organic layer 232 with a molten characteristic can be used as a photoresist layer for defining a contact hole. Then, the contact hole 334 is formed by using an etching process, as shown in FIG. 23. Noticeably, the organic layer 332 is preserved after forming the contact hole 334. A baking process is performed to smoothen the organic layer 332, so that an organic layer 232a with a smooth surface is obtained. As a result, the bumps have smooth surfaces and can have better effects on scattering light beams, as shown in FIG. 24. After that, a metal reflective layer 336 is formed on the structure shown in FIG. 24, as shown in FIG. 25. Thus, the bumpy reflector of the present invention is completed.

In the above-mentioned method for manufacturing the bumpy reflector, the orders of defining the contact hole and baking the organic layer can be swapped. That is, the baking process is firstly performed to smoothen the organic layer 332, which is then used as a photoresist layer for defining a contact hole. Thereafter, the contact hole 334 is formed by performing an etching process. After that, the metal reflective layer 336 is formed on the above-mentioned structure. As a result, the bumpy reflector of the present invention is completed.

In the above-mentioned embodiment of the present invention, the organic layer 332 having a molten characteristic and capable of replacing a photoresist layer is utilized. The organic layer 332 is a photosensitive resin, such as PC403 of JSR Corporation. As a result, processes of forming a photoresist layer and removing the photoresist layer are omitted, which is capable of simplifying manufacturing processes for making a reflector of an LCD.

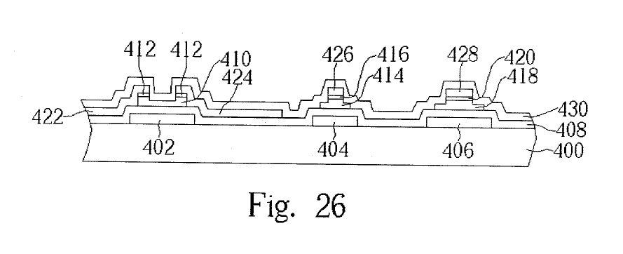

In addition, the present invention provides another method for further simplifying fabrication processes of manufacturing a reflector. FIG. 26 to FIG. 29 are schematic diagrams of manufacturing a bumpy reflector according to the present invention.

According to the process flow shown in FIG. 10 to FIG. 14, gate electrode layers 402, 404, 406 are formed on the substrate 400. The gate electrode layer 402 is used for making a thin film transistor, as well as the gate electrode layers 404, 406 being used for making bumps. An insulating layer 408 is formed on the substrate 400 and the gate electrode layers 402, 404, 406. Then, an amorphous silicon layer 410 and an N⁺ silicon layer 412, which are required by the thin film transistor, are formed. In the meanwhile, amorphous silicon layers 414, 418 and N silicon layers 416, 420, which are required by the bumps, are formed. Thereafter, metal layers 522, 524, 526, 528 are formed. The metal layers 522, 524 are required by the thin film transistor. The metal layers 526, 528 are required by the bumps. After that, an etching process is performed to form the stacked structures, like the stacked structures shown in FIG. 14.

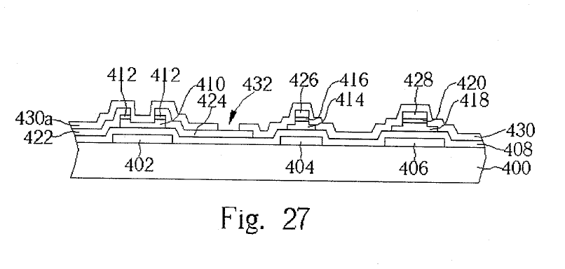

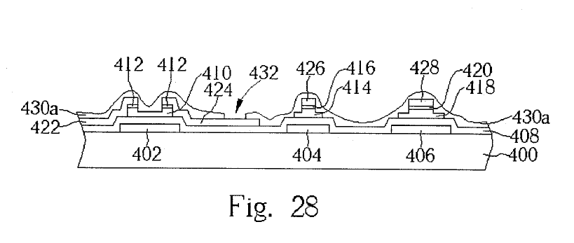

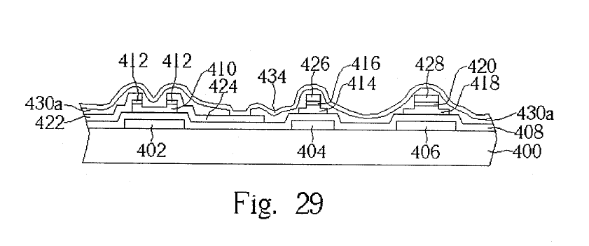

Please refer to FIG. 26. An organic passivation layer 430 is formed on the stacked structures, like the stacked structures shown in FIG. 14. The organic passivation layer 430 is a photosensitive resin having a molten characteristic, so that it can function as a photoresist layer for defining a contact hole. Referring to FIG. 27, an exposing process and a developing process are performed to form a contact hole 432. Additionally, the organic passivation layer 430 is preserved after defining the contact hole 432, and subsequently, a baking process is performed. After the baking process, due to the molten characteristic of the organic passivation layer 430, an organic passivation layer 430a having a smooth surface is formed. Therefore, the bumps have smooth surfaces and have better effects on scattering light beams, as shown in FIG. 28. After that, a metal reflective layer 434 is formed on the structure shown in FIG. 28, as shown in FIG. 29. Thus, the bumpy reflector of the present invention is completed.

In the above-mentioned method for manufacturing the bumpy reflector, order of defining the contact hole and baking the organic layer can be swapped. That is, the baking process is firstly performed to smoothen the organic layer 430, which is then used as a photoresist layer for defining the contact hole. Thereafter, the contact hole 432 is formed by performing an etching process. After that, the metal reflective layer 434 is formed on the above-mentioned structure. As a result, the bumpy reflector of the present invention is completed.

In the above-mentioned embodiment of the present invention, the organic layer 430 has a molten characteristic and is photosensitive, so that the organic layer 430 is capable of replacing a passivation layer and a photoresist layer. As a result, processes of forming an inorganic passivation layer, forming a photoresist layer and removing the photoresist layer are omitted, which can further simplify manufacturing processes for making a reflector of an LCD.

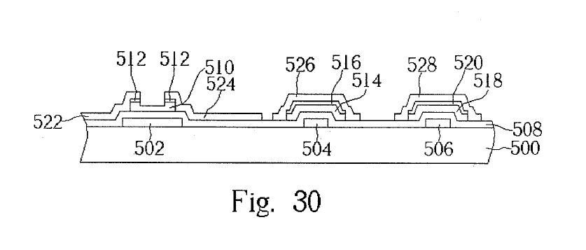

According to the present invention, the method of manufacturing a reflector utilizes a plurality of deposited layers to form the stacked structures of the bumps. The deposition layers are used for manufacturing thin film transistors, such as gate electrode layers, insulating layers, amorphous silicon layers, N⁺ silicon layers, and metal layers. As shown in the above-mentioned figures, the gate electrode layer, the amorphous silicon layer, and the metal layer vary in widths from broadness to narrowness. Furthermore, in another embodiment of the present invention, the gate electrode layer, the amorphous silicon layer, and the metal layer can vary in widths from narrowness to broadness, as shown in FIG. 30. FIG. 30 is a schematic diagram of stacked structures of bumps according to the present invention. Please refer to the process flow shown in FIG. 10 to FIG. 14. A gate electrode layer 502, an amorphous silicon layer 510, an N silicon layer 512, and metal layers 522, 524 are formed on the substrate 500 and they are used for manufacturing thin film transistors. Concurrently, gate electrode layers 504, 506, amorphous silicon layers 514, 518, N⁺ silicon layers 516, 520, and metal layers 526, 528 are formed on the substrate 500 and they are used for making bumps. Additionally, an insulating layer 408 is formed between the amorphous silicon layers and the gate electrode layers for covering the gate electrode layers 502, 504, 506, and the substrate 500.

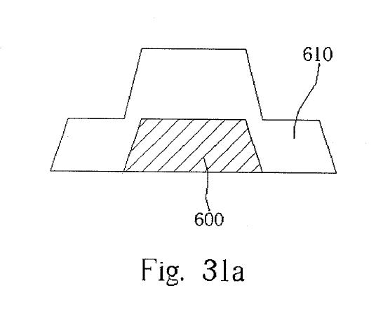

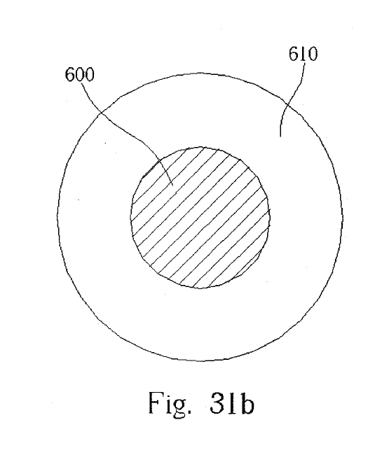

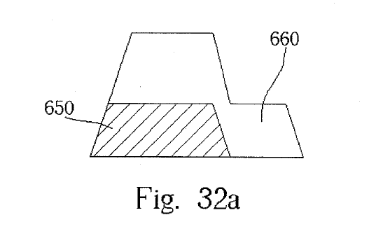

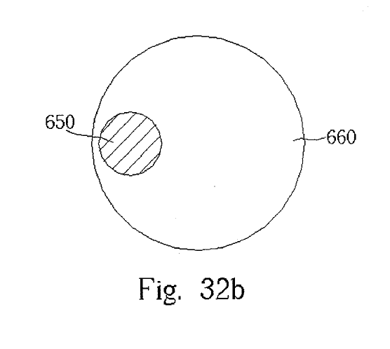

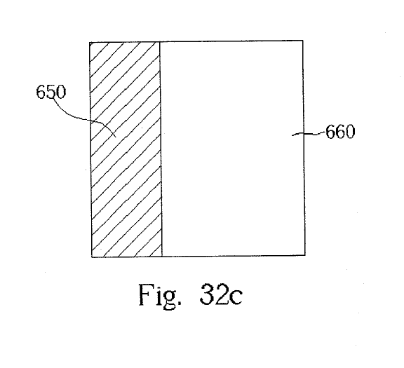

In addition, the thickness of the deposited layers can be altered. Moreover, as positions and shapes of the deposited layers vary, heights of the bumps are therefore changed and then variable bump structures are manufactured. Please refer to FIG. 31a and FIG. 31b. FIG. 31a is a cross-sectional view of a stacked structure of a bump according to the present invention. FIG. 31b is a top view of the stacked structure of the bump shown in FIG. 31a. As shown in FIG. 31a, a deposition layer 610 is formed on a deposition layer 600. Please refer to FIG. 31b. The top view of the stacked structure of the bump is circular and the deposition layer 600 is located in the center of the deposition layer 610, as shown in FIG. 31b. Please refer to FIG. 32a to FIG. 32c. FIG. 32a is a cross-sectional view of another stacked structure of a bump according to the present invention. FIG. 32b and FIG. 32c are top views of the stacked structure of the bump shown in FIG. 32a. As shown in FIG. 32a, the deposition layer 660 deflects to the right of the deposition layer 650 so as to form a slant bump. Moreover, as shown in FIG. 32b and FIG. 32c, shapes of the deposition layers can be varied for manufacturing variable bump structures. As the deposition layer is circular, the top view of the stacked structures of bumps is circular and the deposition layer 650 deflects to the left of the deposition layer 660, as shown in FIG. 32b. In addition, the position of the deposition layer 650 corresponds to the highest position of the bump. In addition, as the shape of the deposition layer is stripe-like, the shape of the bump structure is ladder-shaped, as shown in FIG. 32c. The position of the deposition layer 650 corresponds to the highest position of the bump.

The aforementioned description about gate electrode layer, an amorphous silicon layer, an N⁺ silicon layer, and a metal layer, and the numbers, widths and positions thereof, is merely used as an explanation of an example. They can be varied according to bump structures and requirements of fabrication processes.

The present invention provides a method of manufacturing a reflector for using the deposition layers, which are utilized to make thin film transistors, to define variable reflector structures and the use of photo masks is therefore decreased. Furthermore, an organic layer is used to replace an inorganic passivation layer and a photoresist layer, which is capable of simplifying manufacturing processes of a reflector. Moreover, the reflector structure, which is formed by use of an organic layer having a molten characteristic, has a better effect on reflecting light beams and the quality of an LCD is improved.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of manufacturing a reflector comprising:
providing a substrate;
forming at least one thin film transistor on the substrate;
forming a plurality of stacked structures on the substrate, each of the stacked structures comprising a plurality of sub-stacked layers, which have at least two different kinds of widths;
forming a thin film layer for covering the thin film transistor and the plurality of stacked structures;
forming a contact hole in the thin film layer; and
depositing a reflective metal layer on the thin film layer;
wherein the reflective metal layer is electrically connected to the thin film transistor through the contact hole.

2. The method of claim 1 wherein the thin film transistor and the plurality of stacked structures are formed on the substrate simultaneously.

3. The method of claim 1 wherein the thin film transistor and the plurality of stacked structures are formed on the substrate asynchronously.

4. The method of claim 1 wherein the thin film layer is a laminated layer comprising a photoresist layer, an organic layer, and an inorganic passivation layer.

5. The method of claim 4 wherein a method of forming the contact hole comprises:
forming the inorganic passivation layer on the thin film transistor and the plurality of stacked structures;
forming the organic layer on the inorganic passivation layer;
forming the photoresist layer on the organic layer;
performing a photolithography process for forming a predetermined pattern in the photoresist layer;
etching the organic layer and the inorganic passivation layer along the predetermined pattern so as to form the contact hole;
removing the photoresist layer; and
performing a baking process for smoothening the organic layer.

6. The method of claim 1 wherein the thin film layer is a laminated layer comprising an organic layer and an inorganic passivation layer, and the organic layer is made of a photoresist material.

7. The method of claim 6 wherein a method of forming the contact hole comprises:
forming the inorganic passivation layer on the thin film transistor and the plurality of stacked structures;
forming the organic layer on the inorganic passivation layer;
performing a photolithography process for forming a predetermined pattern in the organic layer;
etching the inorganic passivation layer along the predetermined pattern so as to form the contact hole; and
performing a baking process for smoothening the organic layer.

8. The method of claim 1 wherein the thin film layer is an organic passivation layer, which is made of a photoresist material.

9. The method of claim 8 wherein a method of forming the contact hole comprises:
forming the organic passivation layer on the thin film transistor and the plurality of stacked structures;
performing an exposing process for forming a predetermined pattern in the organic passivation layer;
performing a developing process on the organic passivation layer so as to form the contact hole; and
performing a baking process for smoothening the organic passivation layer.

10. The method of claim 1 wherein each of the sub-stacked layers is formed from a material selected from the group consisting of an insulating layer, a gate electrode layer, an amorphous silicon layer, an N⁺ silicon layer, and a metal layer.

11. The method of claim 1 wherein each of the sub-stacked layers is formed from a material selected from the group consisting of a gate electrode,a common electrode, an insulating layer, an amorphous silicon layer, an N⁺ silicon layer, a metal layer, a source electrode, a drain electrode, and a passivation layer.
